(19) United States
(12) Patent Application Publication
(10) Pub. No.: US 2015/0206910 A1
(43) Pub. Date: Jul. 23, 2015

(54) SOLID-STATE IMAGING DEVICE, IMAGING SYSTEM, AND COPIER

(71) Applicant: Canon Kabushiki Kaisha, Tokyo (JP)

(72) Inventor: Satoshi Kato, Kawasaki-shi (JP)

(21) Appl. No.: 14/601,025

(22) Filed: Jan. 20, 2015

(30) Foreign Application Priority Data
Jan. 21, 2014 (JP) 2014-008802

(51) Int. Cl. H01L 27/146; H04N 1/028

(52) U.S. Cl. CPC H01L 27/14605; H01L 27/14643; H04N 1/028

(57) ABSTRACT

Each of a plurality of cells includes first and second photoelectric conversion units, and an interval of the first and second photoelectric conversion units in a sub-scanning direction is {n+(b/a)}×x, where a is a period from when the first and second photoelectric conversion units terminate electric carrier accumulation to when the first and second photoelectric conversion units performs the electric carrier accumulation again and next terminate the electric carrier accumulation, b is a gap of timing at which the first and second photoelectric conversion units terminate the electric carrier accumulation, n is an integer of 1 or more, and x is an interval of the first and second photoelectric conversion unit in a main scanning direction.

### BACKGROUND OF THE INVENTION

1. Field of the Invention

One disclosed aspect of the embodiments relates to a solid-state imaging device, an imaging system, and a copier, used in a copier, an image scanner, and the like.

2. Description of the Related Art

In recent years, reduction of the pixel size tends to be required for solid-state imaging devices with an increase in the number of pixels with improvement of the resolution. As a technology to respond to the reduction of the pixel size, a pixel sharing technology as described in Japanese Patent Application Laid-Open No. 9-46596 is known. In Japanese Patent Application Laid-Open No. 9-46596, a circuit of and after a floating diffusion is shared by a plurality of pixels (photodiodes), so that the reduction of the pixel size is achieved.

### SUMMARY OF THE INVENTION

A solid-state imaging device of an embodiment is a solid-state imaging device configured to be relatively scanned in a first direction with respect to an original copy, and including: a plurality of cells; and a memory, wherein each of the plurality of cells includes a first photoelectric conversion unit configured to convert light into electric carriers and accumulate the electric carriers, and a second photoelectric conversion unit arranged in the first direction with respect to the first photoelectric conversion unit, and configured to convert light into electric carriers and accumulate the electric carriers, the memory is provided common to the first and second photoelectric conversion units, and holds the electric carriers accumulated by each of the first and second photoelectric conversion units, or signals based on the electric carries, and an interval of the first and second photoelectric conversion units of one cell of the plurality of cells in the first direction is {n+(b/a)}×x, where a is a period from when the first and second photoelectric conversion units terminate an electric carrier accumulation to when the first and second photoelectric conversion units perform the electric carrier accumulation again and next terminate the electric carrier accumulation, b is a gap of timing at which the electric carrier accumulation of the first and second photoelectric conversion units is terminated, n is an integer of 1 or more, and x is an interval of the first photoelectric conversion unit of the one cell of the plurality of cells, and the first photoelectric conversion unit of another cell adjacent to the one cell in a second direction perpendicular to the first direction.

Further features of the disclosure will become apparent from the following description of exemplary embodiments (with reference to the attached drawings).

### BRIEF DESCRIPTION OF THE DRAWINGS

FIG. 1 is a diagram illustrating a configuration example of a solid-state imaging device according to a first embodiment.

FIG. 2 is a diagram illustrating a configuration example of a pixel cell of FIG. 1.

FIG. 3 is a timing chart of the pixel cell of FIG. 1.

FIG. 4 is a diagram illustrating a layout configuration example of the pixel region of FIG. 1.

FIG. 5 is a diagram illustrating a configuration example of a pixel cell, which is different from FIG. 2.

FIG. 6 is a timing chart of the pixel cell of FIG. 5.

FIG. 7 is a diagram illustrating a layout configuration example of the pixel region of FIG. 1.

FIG. 8 is a diagram illustrating a configuration example of a solid-state imaging device.

FIG. 9 is a diagram illustrating a configuration example of the pixel region of FIG. 8.

FIG. 10 is a timing chart of the pixel region of FIG. 8.

FIG. 11 is a timing chart of the pixel region of FIG. 8.

FIG. 12 is a diagram illustrating a layout configuration example of the pixel region of FIG. 8.

FIG. 13 is a diagram illustrating a configuration example of a solid-state imaging device according to a second embodiment.

FIG. 14 is a diagram illustrating a layout configuration example of a pixel region of FIG. 13.

FIG. 15 is a diagram illustrating a configuration example of an imaging system according to a third embodiment.

### DESCRIPTION OF THE EMBODIMENTS

However, when the technology of Japanese Patent Application Laid-Open No. 9-46596 is applied to a line sensor used in a copier or the like, the following problems are caused. In the technology described in Japanese Patent Application Laid-Open No. 9-46596, a plurality of pixel signals is read out by a single readout circuit. Therefore, readout timing of pixels that share the floating diffusion is different. That is, among the pixels that share a memory, which holds electric carriers accumulated by each of a plurality of photoelectric conversion units or signals based on the electric carriers, timing at which electric carrier accumulation is terminated is shifted. Accordingly, a gap is caused in imaging positions, which causes a decrease in image quality such as deterioration of a fixed-pattern noise and degradation of the resolution represented by color degrading.

An objective of an embodiment is to provide a solid-state imaging device, an imaging system, and a copier, which can decrease the fixed-pattern noise and the color degrading caused by the gap of timing at which the electric carrier accumulation is terminated.

### First Embodiment

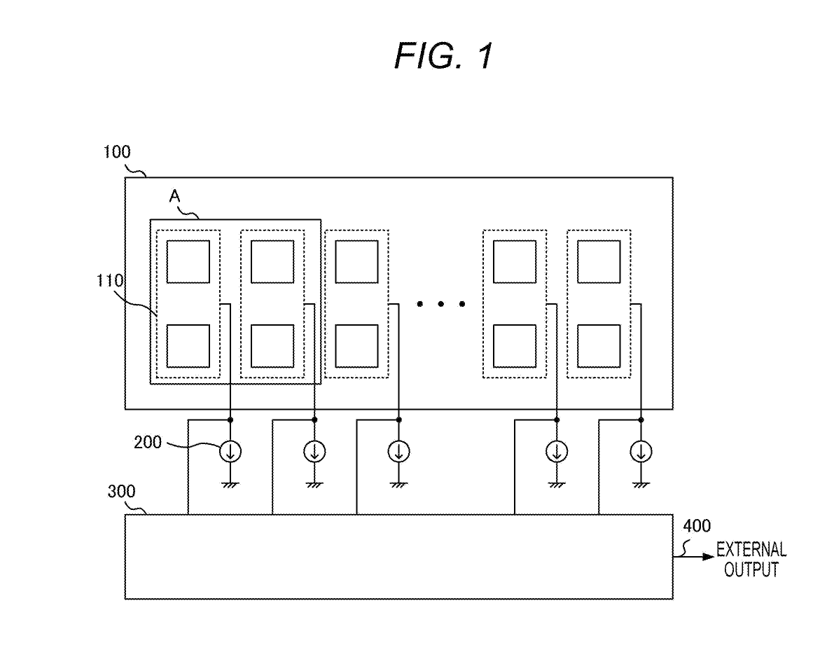

FIG. 1 is a diagram illustrating a configuration example of a solid-state imaging device according to a first embodiment. A pixel array 100 includes a plurality of pixel cells 110 arranged in one dimensional manner, and outputs a plurality of pixel signals according to incident light. Each of a plurality of current sources 200 is a current source for operating an amplifier in each of the plurality of pixel cells 110 at a predetermined operating point. A signal processing circuit 300 processes the pixel signals input from the pixel array 100, and outputs the processed signals to an external output line 400. The solid-state imaging device is a line sensor used for a copier or the like, and can generate a two-dimensional image by being relatively scanned with respect to an original copy. The copier includes the solid-state imaging device and a signal processing unit that processes signals output from the solid-state imaging device. The copier performs printing using signals that are the signals output by the solid-state imaging device and processed by the signal processing unit.

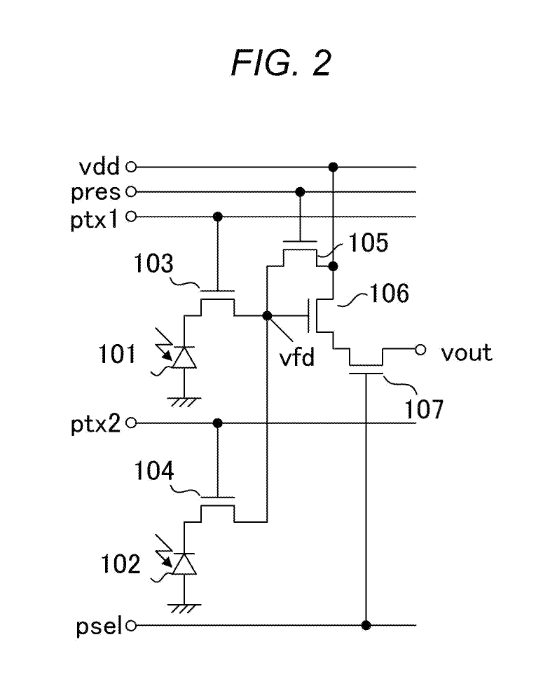

FIG. 2 is a circuit diagram illustrating a configuration example of the pixel cell 110 of FIG. 1. Each pixel cell 110 includes a first photoelectric conversion unit 101, a second photoelectric conversion unit 102, a first transfer transistor 103, a second transfer transistor 104, a reset transistor 105, an amplification transistor 106, and a selection transistor 107. The photoelectric conversion units 101 and 102 are photodiodes, for example, and convert light into electric carriers and accumulate the converted electric carriers. Here, the photodiodes 101 and 102 have mutually different spectral sensitivity characteristics. Pixel outputs of the photodiodes 101 and 102 based on the electric carriers are subjected to image processing as respective single pixel signals in the end. A floating diffusion vfd accumulates the electric carriers. The first transfer transistor 103 transfers the electric carriers accumulated in the photodiode 101 to the floating diffusion vfd in response to a pulse ptx1. The second transfer transistor 104 transfers the electric carriers accumulated in the photodiode 102 to the floating diffusion vfd in response to a pulse ptx2. The reset transistor 105 resets the floating diffusion vfd to a power source potential (reset voltage) vdd in response to a pulse pres. The amplification transistor 106 amplifies and outputs the potential of the floating diffusion vfd. The selection transistor 107 outputs an output signal of the amplification transistor 106 to an output terminal vout in response to a pulse psel. The output terminal vout is connected to the current source 200 and the signal processing circuit 300 of FIG. 1.

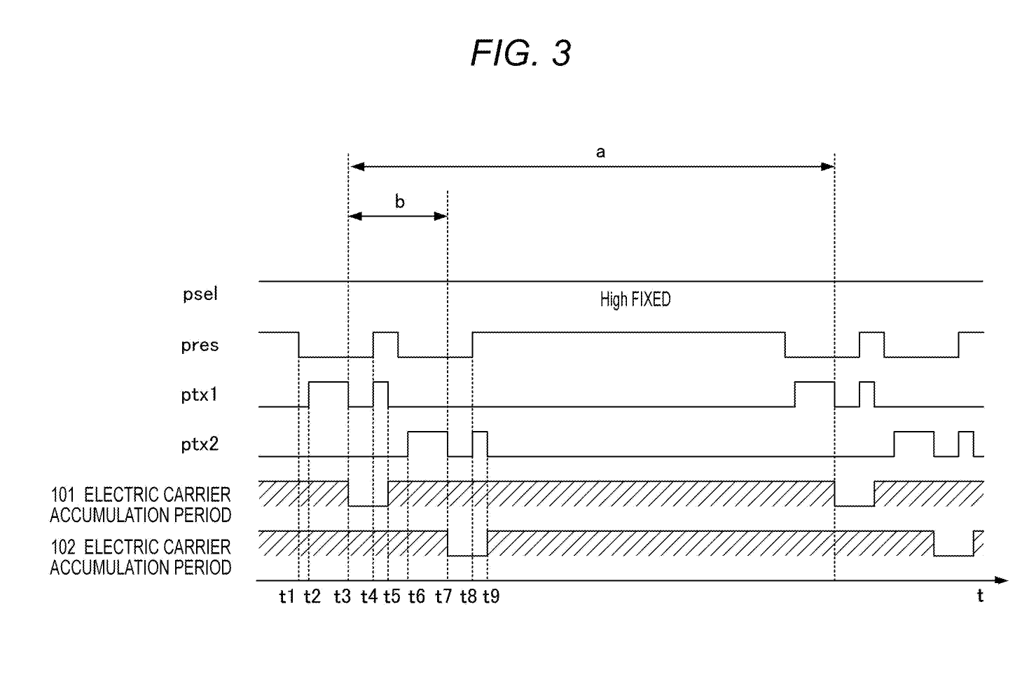

One disclosed feature of the embodiments may be described as a process which is usually depicted as a timing chart or timing diagram. A timing diagram may illustrate the timing relationships of several entities, such as signals, events, etc. Although a timing diagram may describe the operations as a sequential process, some operations may be performed in parallel or concurrently. In addition, unless specifically stated, the order of the operations or timing instants may be re-arranged. Furthermore, the timing or temporal distances may not be scaled or depict the timing relationships in exact proportions. FIG. 3 is a timing chart illustrating a method of controlling the pixel cell 110 of FIG. 2. At time t1, the pulse pres becomes a low level, the reset transistor 105 is OFF, and the reset of the floating diffusion vfd is cancelled. At time t2, the pulse ptx1 becomes a high level, the transfer transistor 103 is ON, and transfer of the electric carriers from the photodiode 101 to the floating diffusion vfd is started. At time t3, the pulse ptx1 becomes a low level, the transfer transistor 103 is OFF, and the transfer of the electric carriers from the photodiode 101 to the floating diffusion vfd is terminated. Note that the time t3 means the end of an electric carrier accumulation period of the photodiode 101. The period before the time t3 is the electric carrier accumulation period in which the photodiode 101 converts incident light into the electric carriers and accumulates the electric carriers. The amplification transistor 106 outputs a voltage according to the electric carriers of the floating diffusion vfd to the output terminal vout through the selection transistor 107.

At time t4, the pulses pres and ptx1 becomes a high level, the reset transistor 105 and the transfer transistor 103 are ON, and the photodiode 101 and the floating diffusion vfd are reset to the power source potential vdd. At time t5, the pulse ptx1 becomes a low level, the transfer transistor 103 is OFF, and the reset of the photodiode 101 is terminated. At the same time, the solid-state imaging device is relatively scanned with respect to an original copy, and the electric carrier accumulation period of the next row of the photodiode 101 is started. Following that, the pulse pres becomes a low level, and the reset transistor 105 is OFF.

At time t6, the pulse ptx2 becomes a high level, the transfer transistor 104 is ON, and transfer of the electric carriers from the photodiode 102 to the floating diffusion vfd is started. At time t7, the pulse ptx2 becomes a low level, the transfer transistor 104 is OFF, and the transfer of the electric carriers from the photodiode 102 to the floating diffusion vfd is terminated. The time t7 means the end of the electric carrier accumulation period of the photodiode 102. The period before the time t7 is the electric carrier accumulation period in which the photodiode 102 converts the incident light into the electric carriers, and accumulates the electric carriers. The amplification transistor 106 outputs a voltage according to the electric carriers of the floating diffusion vfd to the output terminal vout through the selection transistor 107.

At time t8, the pulses pres and ptx2 become a high level, the reset transistor 105 and the transfer transistor 104 are ON, and the photodiode 102 and the floating diffusion vfd are reset to the power source potential vdd. At time t9, the pulse ptx2 becomes a low level, the transfer transistor 103 is OFF, and the reset of the photodiode 102 is terminated. At the same time, the solid-state imaging device is relatively scanned with respect to the original copy, and the electric carrier accumulation period of the next row of the photodiode 102 is started.

Following that, the processing of the time t1 and subsequent steps is repeated. One period of the above operation (for example, a period from the time t3 to the next time t3) is a. That is, the period a is a readout period of the electric carriers of the photodiodes 101 and 102. Further, a gap between the electric carrier accumulation end time t3 of the photodiode 101 and the electric carrier accumulation end time t7 of the photodiode 102 is a gap b of timing at which the electric carrier accumulation of the photodiodes 101 and 102 is terminated. The gap b of the timing at which the electric carrier accumulation of the photodiodes 101 and 102 is terminated is also a gap between the electric carrier accumulation start time t5 of the photodiode 101 and the electric carrier accumulation start time t9 of the photodiode 102.

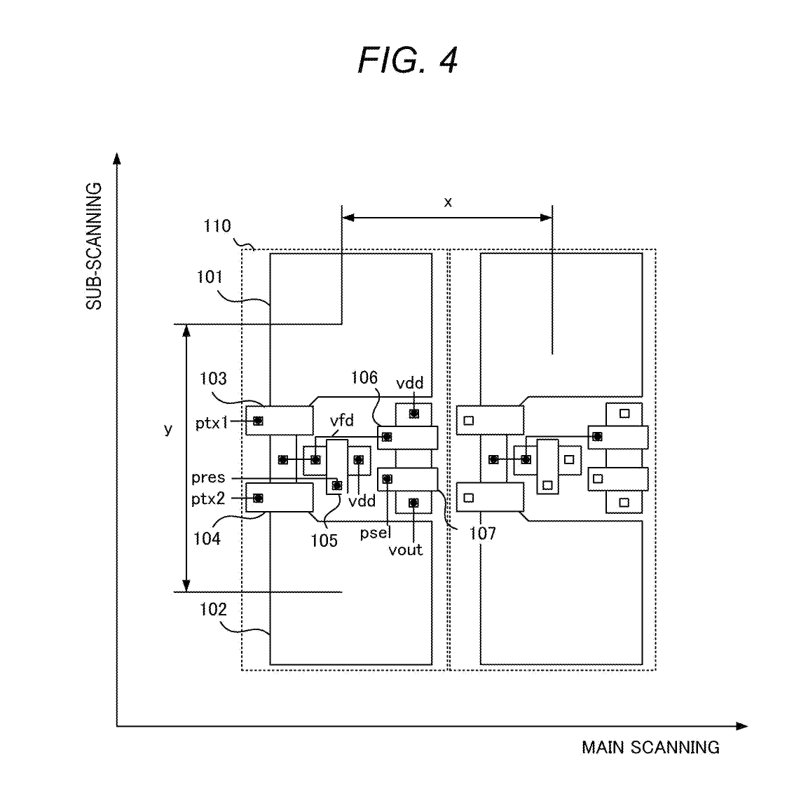

FIG. 4 is a diagram illustrating a layout configuration example of a pixel region A of FIG. 1. The same member as FIGS. 1 and 2 is denoted with the same reference number. As illustrated in FIG. 4, a sub-scanning direction (first direction) is a direction into which the solid-state imaging device is relatively scanned with respect to the original copy. A main scanning direction (second direction) is a direction (vertical direction) perpendicular to the sub-scanning direction. The plurality of pixel cells 110 is provided on the same semiconductor substrate. The photodiodes 101 and 102 are arrayed (arranged) in the sub-scanning direction. That is, the photodiodes 101 and 102 are arrayed in the sub-scanning direction that is the vertical direction with respect to the main scanning direction into which the plurality of pixel cells 110 is arrayed. Here, an interval of the plurality of pixel cells 110 arrayed in the main scanning direction is x, and an interval of the photodiodes 101 and 102 arrayed in the sub-scanning direction is y. The plurality of pixel cells 110 is arrayed in the main scanning direction at the interval x. The interval x is an interval of the photodiodes in the main scanning direction. The interval y is an interval of the photodiodes 101 and 102 in the sub-scanning direction. The interval x is a distance between the center of gravity of the photodiode 101 of the pixel cell 110 and the center of gravity of the photodiode 101 included in the adjacent pixel cell 110. Further, the interval y is a distance between the center of gravity of the photodiode 101 of the pixel cell 110 and the center of gravity of the photodiode 102 included in the same pixel cell 110.

Next, characteristics of image reading using the solid-state imaging device (line sensor) will be described. In the line sensor, imaging positions are shifted between the photodiodes 101 and 102 due to the physical gap (regular interval) y of imaging positions on an original image, of pixels corresponding to the photodiodes 101 and 102. Therefore, in a typical line sensor, a function to correct the gap of the imaging positions with respect to the output images of the photodiodes 101 and 102 may be provided. When the line sensor or the original copy is being moved in the sub-scanning direction, a positional relationship between the photodiodes 101 and 102 is always maintained constant. Therefore, the imaging positions of the pixels on the same time are shifted by the amount corresponding to the interval y. When y is an integral multiple of the pixel pitch x in the main scanning direction (y=n×x, n is an integer of 1 or more), the gap between the imaging positions can be decreased if images are synthesized after being shifted by n×x rows in correction by the processing circuit of a following stage. However, when a gap is caused between the imaging positions of the photodiodes 101 and 102 due to the gap b of the timing at which the electric carrier accumulation of the photodiodes 101 and 102 is terminated, this gap is remained as a component that cannot be removed in the above correction. To be specific, when an imaging range in the readout period a corresponds to the pixel pitch x in the main scanning direction on one-to-one basis, the gap between the imaging positions of the photodiodes 101 and 102 can be expressed by (b/a)×x. A gap of the imaging positions is caused between the photodiodes 101 and 102 by the gap. Note that, here, the electric carrier accumulation period is determined by the pulses ptx1, ptx2, and pres. That is, the gap b of the timing at which the electric carrier accumulation of the photodiodes 101 and 102 is terminated is a gap of operation timing of the transfer transistors 103 and 104, and the reset transistor 105.

Therefore, in the present embodiment, the pixel pitch y in the sub-scanning direction is shifted by the gap (b/a)×x. With the gap of the imaging positions caused due to the shift, the gap of the imaging positions caused due to the gap of timing at which the electric carrier accumulation at the time of sharing pixels is terminated is decreased, whereby the image quality is improved. That is, the pixel pitch y is set to satisfy the relationship expressed by the following formula (1).

y={n+(b/a)}×x (1)

Note that, under the conditions of use of a copier or the like using a real line sensor, there is influence of an aberration and the like that an optical member such as a lens has, as a factor to cause the gap of the imaging positions described above. When considering the influence, a variable c is added to the formula (1), as expressed by the following formula (2).

y={n+(b/a)+c}×x (2)

Here, an absolute value of c is supposed to be a value from 0.1 to 0.15, both inclusive. However, in the present embodiment, y is not changed according to the variable c. Although depending on the specification, the period a and the gap b becomes b/a=0.2 where a=100 μs, and b=20 μs. Effect to reduce the influence of the image gap is substantial by the correction of this b/a.

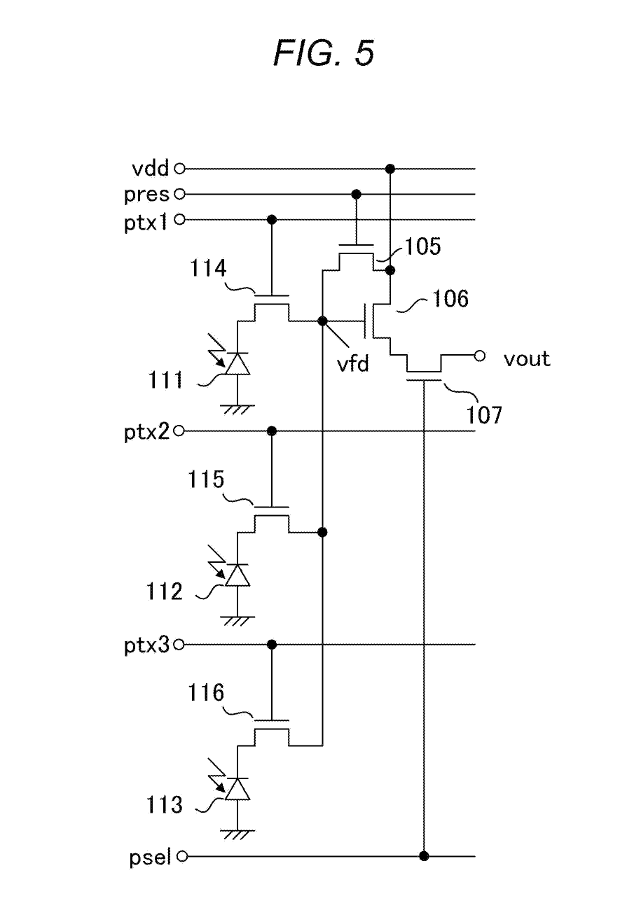

Further, the pixel cell 110 is not limited to the configuration of two pixel sharing of FIG. 2, and the same applies to the following embodiments. For example, similar effects can be obtained in a configuration where the pixel cell 110 shares three or more pixels, as illustrated in FIGS. 5 to 7.

FIG. 5 is a diagram illustrating a configuration example of the pixel cell 110 that shares three pixels. Three photodiodes 111 to 113 correspond to three pixels. Three transfer transistors 114 to 116 respectively transfer the electric carriers photo-electrically converted by the photodiodes 111 to 113 to the floating diffusion vfd in response to pulses ptx1 to ptx3. Transistors 105 to 107 are similar to those in FIG. 2.

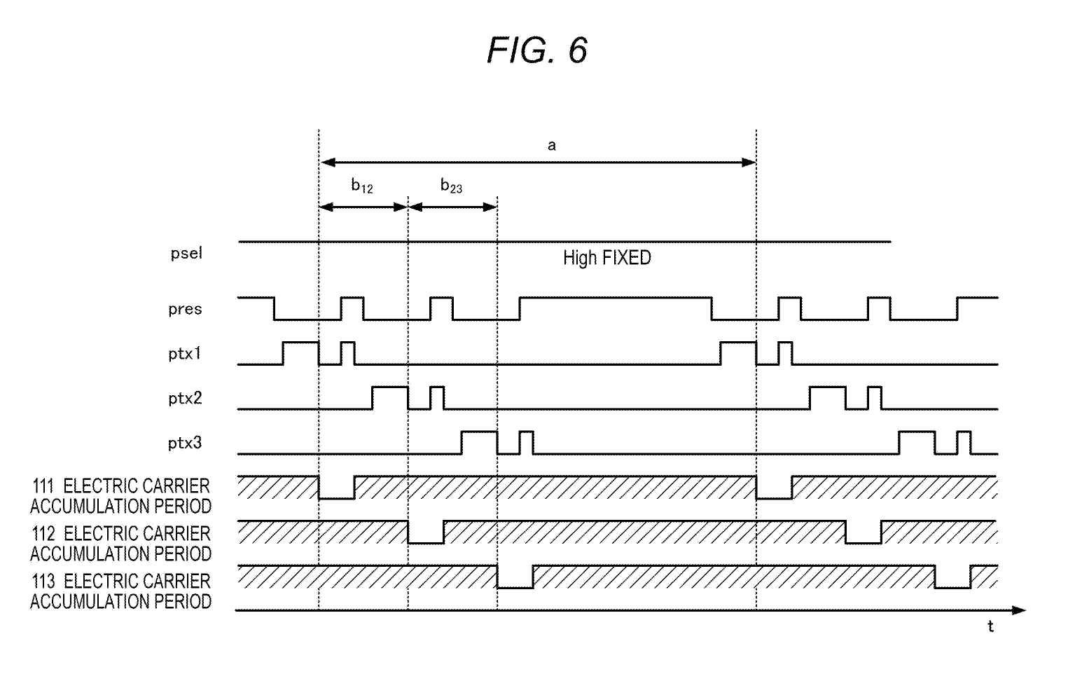

FIG. 6 is a timing chart illustrating a method of controlling the pixel cell 110 of FIG. 5. The gap of timing at which the electric carrier accumulation of the photodiodes 111 and 112 is terminated is b12, and the gap of timing at which the electric carrier accumulation of the photodiodes 112 and 113 is terminated is b23. The readout period is a.

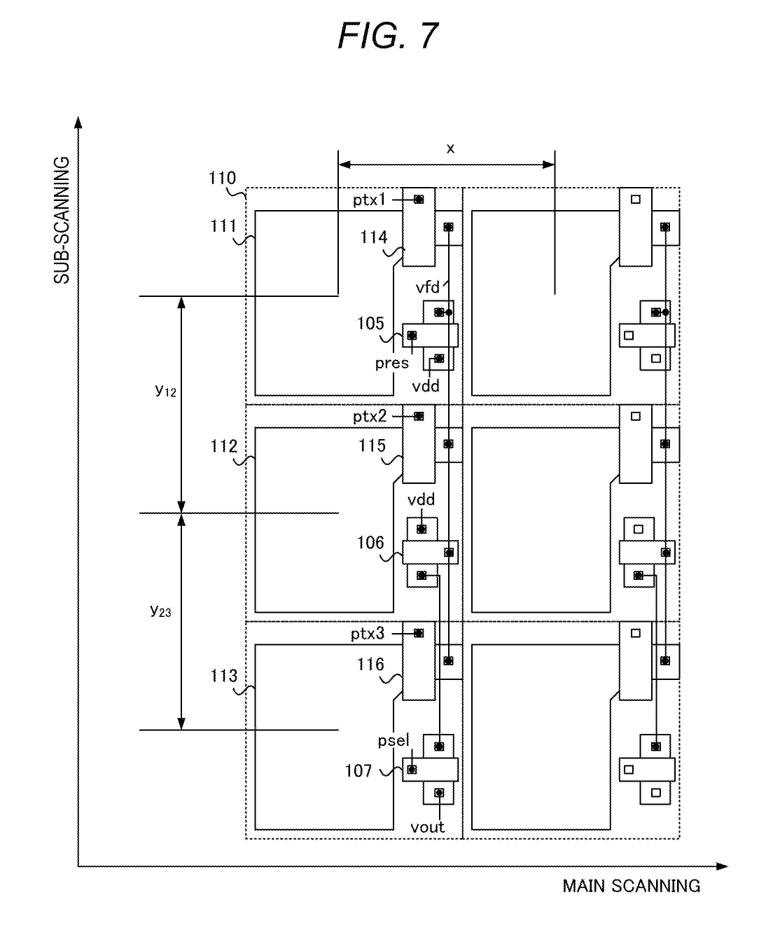

FIG. 7 is a diagram illustrating a layout configuration example of a pixel region A in which three pixels are shared. The same member as FIGS. 1 and 5 is denoted with the same reference sign. A pixel pitch y12 is an interval of the photodiodes 111 and 112 arrayed in the sub-scanning direction. A pixel pitch y23 is an interval of the photodiodes 112 and 113 arrayed in the sub-scanning direction. The pixel pitches y12 and y23 are respectively expressed by the following formulas (3) and (4), similarly to the formula (2).

y12={n+(b12/a)}×x (3)

y23={n+(b23/a)}×x (4)

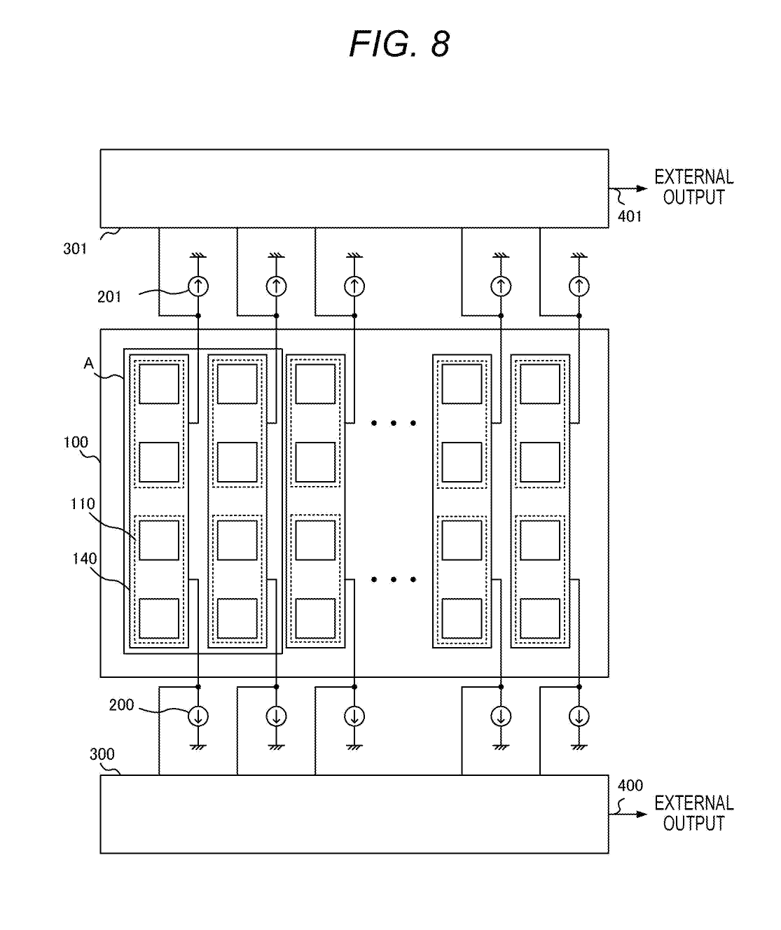

Further, a pixel cell 110 having the pixel pitch y (y12, y23) in the sub-scanning direction of an integral multiple of the pixel pitch x in the main scanning direction may be included, depending on operating conditions of the pixels. An example thereof will be described with reference to FIGS. 8 to 12.

FIG. 8 is a diagram illustrating a configuration example of a solid-state image device of when two pixel cells 110 are arrayed in the sub-scanning direction. A plurality of pixel regions 140 is arrayed in the main scanning direction. In the pixel region 140, two pixel cells 110 are arrayed in the sub-scanning direction. The output terminal of the lower-side pixel cell 110 is connected to the current source 200 and the signal processing circuit 300. The signal processing circuit 300 processes the pixel signal input from the pixel cell 110, and outputs the processed signal to the external output line 400. The output terminal of the upper-side pixel cell 110 is connected to a current source 201 and a signal processing circuit 301. The signal processing circuit 301 processes the pixel signal input from the pixel cell 110, and outputs the processed signal to an external output line 401.

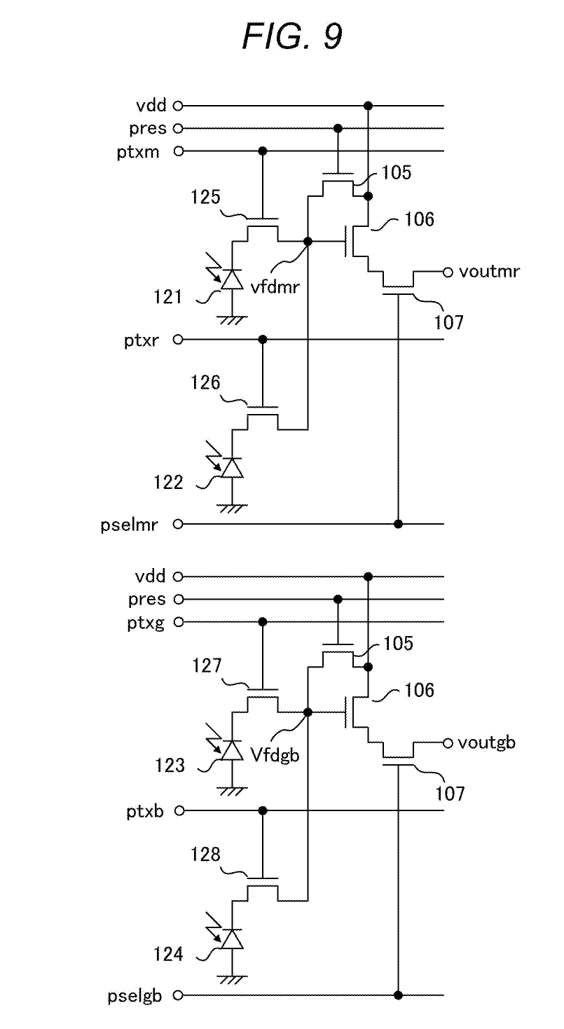

FIG. 9 is a diagram illustrating a configuration example of the pixel region 140 of FIG. 8. In the upper-side pixel cell 110, two transfer transistors 125 and 126 respectively transfer the electric carriers photoelectrically converted by two photodiodes 121 and 122 to a floating diffusion vfdmr in response to pulses ptxm and ptxr. Then, the pixel signals are output from an output terminal voutmr. In the lower-side pixel cell 110, two transfer transistors 127 and 128 respectively transfer the electric carriers photoelectrically converted by two photodiodes 123 and 124 to a floating diffusion vfdgb in response to pulses ptxg and ptxb. Then, the pixel signals are output from an output terminal voutgb. Here, the photodiode 121 is a photodiode PD_M of a monochromatic pixel, and the photodiodes 122, 123, and 124 are photodiodes PD_R, PD_G, and PD_B having spectral sensitivity characteristics respectively corresponding to the three colors of red (R), green (G), and blue (B). The solid-state imaging device of the present embodiment is operated in a mode selected from a mode group including a first mode and a second mode. The first mode is a mode in which the photodiode PD_M does not output the pixel signal, and each of the photodiodes PD_R, PD_G, and PD_B outputs the pixel signal. The second mode is a mode in which each of the photodiodes PD_R, PD_G, and PD_B does not output the pixel signal, and the photodiode PD_M outputs the pixel signal.

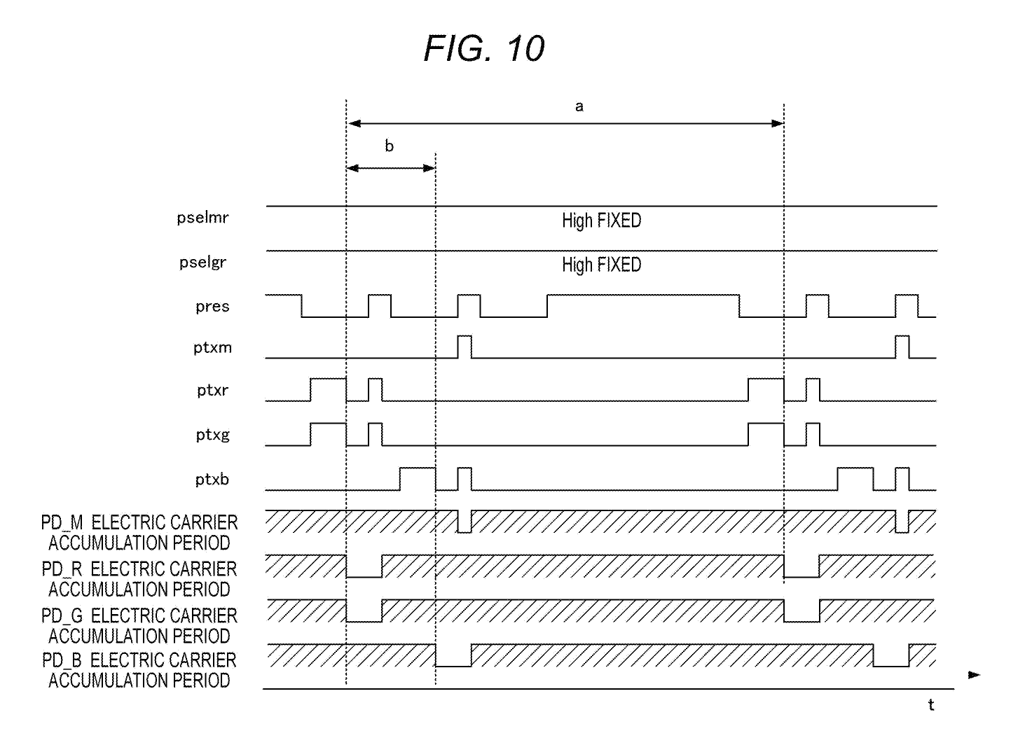

FIG. 10 is a timing chart illustrating a control method of when only the photodiodes PD_R, PD_G, and PD_B are read out as the first mode. The relationship between the photodiodes PD_G and PD_B is the same as that of the photodiodes 101 and 102 described above. In contrast, the photodiode PD_M is not operated other than by a reset operation. The photodiode PD_R is operated at the same timing as the photodiode PD_G.

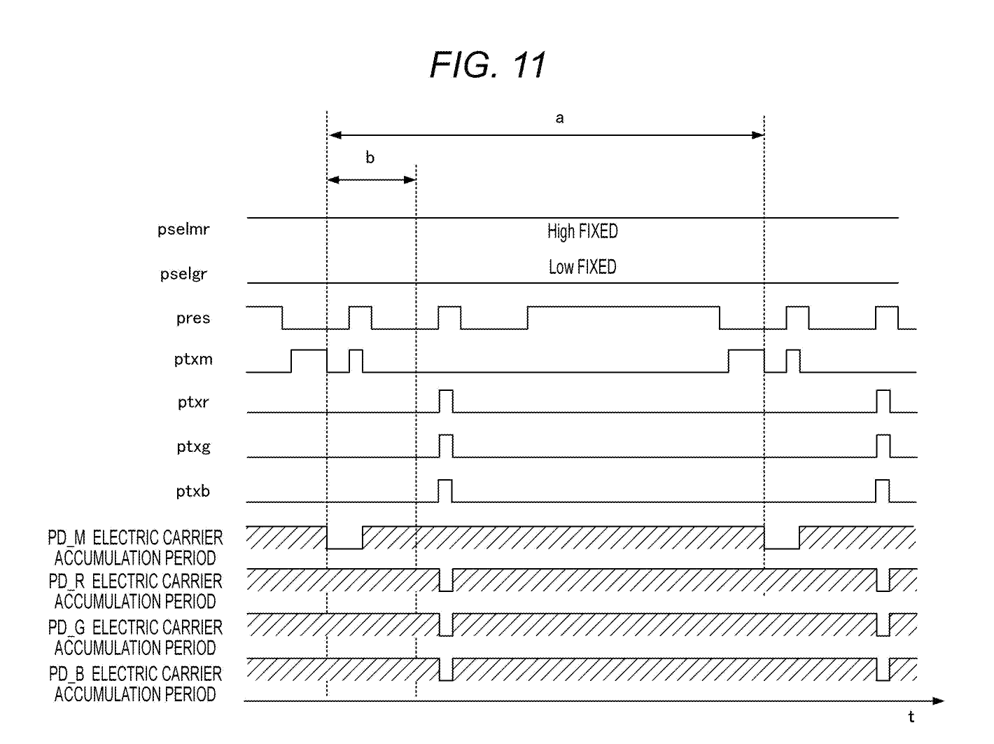

FIG. 11 is a timing chart illustrating a control method of when only the photodiode PD_M is read out as the second mode. The readout of the electric carriers is performed only in the photodiode PD_M. Only the reset operation is performed in other photodiodes PD_R, PD_G, and PD_B.

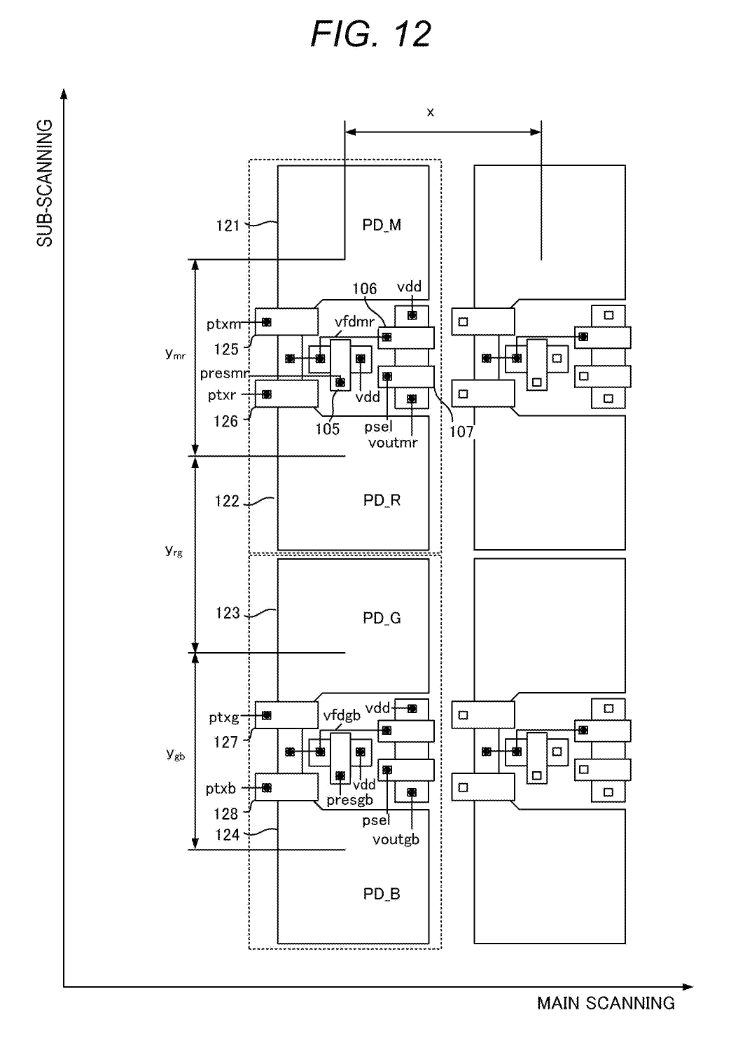

FIG. 12 is a diagram illustrating a layout configuration example of the pixel region A of FIG. 8. A pixel pitch ymr is an interval of the photodiode 121 (PD_M) and the photodiode 122 (PD_R) in the sub-scanning direction. A pixel pitch yrg is an interval of the photodiode 122 (PD_R) and the photodiode 123 (PD_G) in the sub-scanning direction. A pixel pitch ygb is an interval of the photodiode 123 (PD_G) and the photodiode 124 (PD_B) in the sub-scanning direction. The pixel pitch x is an interval of the photodiodes in the main scanning direction.

Because it is not necessary for the pixel pitch ymr to consider the gap of the imaging positions from a point that the pixel signals of the photodiodes PD_M and PD_R are not used in the same image, the pixel pitch ymr can be set to an integral multiple of the pixel pitch x in the main scanning direction, as expressed by the following formula (5).

ymr=n×x (5)

From a point that the timing of the electric carrier accumulation of the photodiodes PD_R and PD_G coincides with each other according to FIG. 10, the pixel pitch yrg can also be set to the integral multiple of the pixel pitch x in the main scanning direction, as expressed by the following formula (6).

yrg=n×x (6)

It is necessary to shift the pixel pitch ygb by the amount corresponding to the gap b of the timing at which the electric carrier accumulation of the photodiodes PD_G and PD_B is terminated, according to FIG. 10. Therefore, the pixel pitch ygb can be expressed by the following formula (7), similarly to the formula (2).

ygb={n+(b/a)}x (7)

As described above, in the present embodiment, the pixel cell 110 having a pixel pitch in the sub-scanning direction of an integral multiple of the pixel pitch x in the main scanning direction can be included depending on the operating conditions of the pixels. By appropriately setting the pixel pitch in the sub-scanning direction, a favorable image with a decreased fixed-pattern noise can be obtained, the noise being caused by the gap of the timing at which the electric carrier accumulation is terminated.

### Second Embodiment

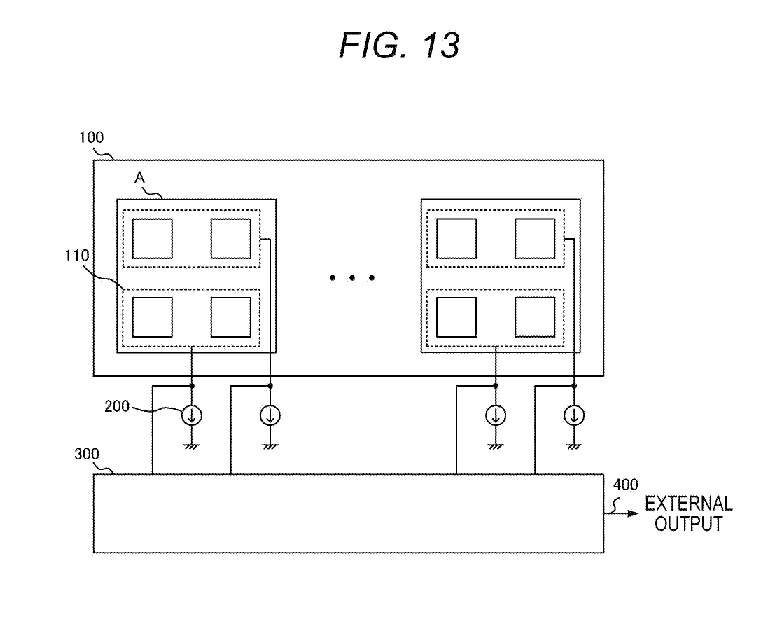

FIG. 13 is a diagram illustrating a configuration example of a solid-state imaging device according to a second embodiment. Hereinafter, different points of the present embodiment from the first embodiment will be described. A pixel cell 110 shares two pixels arrayed in a main scanning direction. Further, two pixel cells 110 are arrayed in a sub-scanning direction.

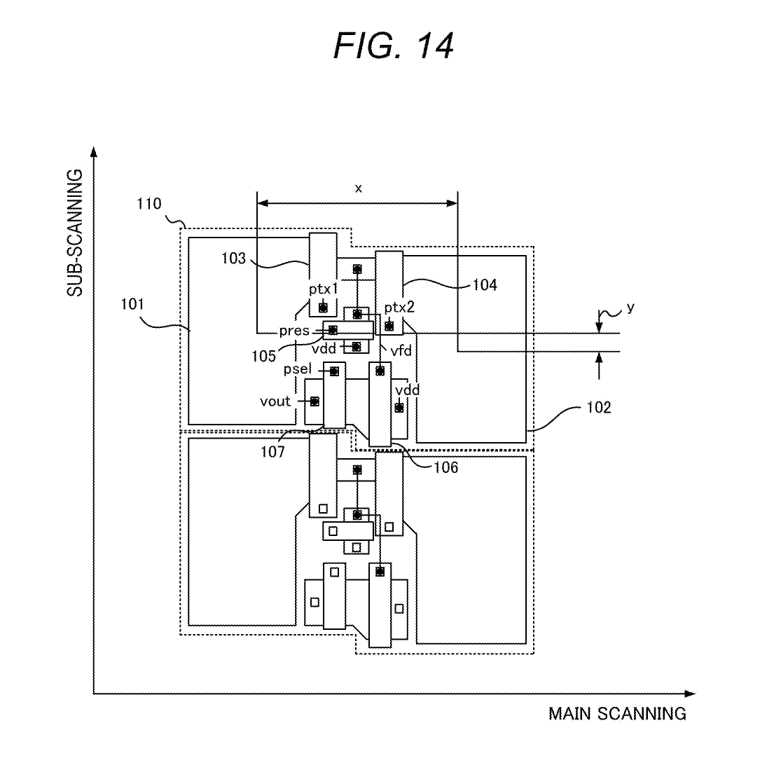

FIG. 14 is a diagram illustrating a layout configuration example of a pixel region A of FIG. 13. The same member as FIG. 2 is denoted with the same reference sign. Note that a circuit configuration and operation timing of the pixel cell 110 are the same as FIGS. 2 and 3. A plurality of pixel cells 110 is arrayed in the sub-scanning direction. Photodiodes 101 and 102 of the same pixel cell (same cell) 110 are arrayed in the main scanning direction at an interval x. An interval y is an interval of the photodiodes 101 and 102 in the sub-scanning direction. The interval y of the photodiodes 101 and 102 in the sub-scanning direction of the same pixel cell (same cell) 110 can be expressed by the following formula (8) according to a similar method of thinking to the formula (2).

y=(b/a)×x (8)

A pixel pitch y of the present embodiment is different from the first embodiment, and becomes a pixel pitch of when a variable n is 0 in the formula (1), as expressed by the formula (8), and thus the variable n disappears. When considering the first and second embodiments, the variable n of the formula (1) is an integer of 0 or more. When sharing two pixels arrayed in the main scanning direction, by setting the pixel pitch y, like the formula (8), a favorable image with a decreased fixed-pattern noise can be obtained, the noise being caused by a gap of timing at which electric carrier accumulation is terminated. In the present embodiment, in consideration of influence of an aberration and the like that an optical member such as a lens has, a variable c may be added to the formula (8), as expressed by the following formula (9). Here, an absolute value of c is supposed to be a value from 0.1 to 0.15, both inclusive.

y={(b/a)+c}×x (9)

Note that, in the first and second embodiments, examples have been described, in which the memory that holds the electric carriers accumulated by the first and second photoelectric conversion units is a floating diffusion. As another example, the memory may hold the signal, which is output by the amplification transistor 106, based on the electric carriers accumulated by the first and second photoelectric conversion units. That is, the memory is shared by the first and second photoelectric conversion units, and may just have a configuration to hold the electric carriers accumulated by the first and second photoelectric conversion units or the signals based on the electric carriers.

Note that the interval x is the distance between the center of gravity of the photodiode 101 of the pixel cell 110 and the center of gravity of the photodiode 101 included in the adjacent pixel cell 110. As another example, a distance between a left end of the photodiode 101 included in the pixel cell 110 and a left end of the photodiode 101 include in the adjacent pixel cell 110 may be employed as the interval x. Similarly, a distance between a right end of the photodiode 101 included in the pixel cell 110 and a right end of the photodiode 101 included in the adjacent pixel cell 110 may be employed as the interval x.

Further, the interval y is the distance between the center of gravity of the photodiode 101 of the pixel cell 110 and the center of gravity of the photodiode 102 included in the same pixel cell 110. As another example, a distance between an upper end of the photodiode 101 included in the pixel cell 110 and an upper end of the photodiode 102 included in the same pixel cell 110 may be employed as the interval y. Similarly, a distance between a lower end of the photodiode 101 included in the pixel cell 110 and a lower end of the photodiode 102 included in the same pixel cell 110 may be employed as the interval y.

### Third Embodiment

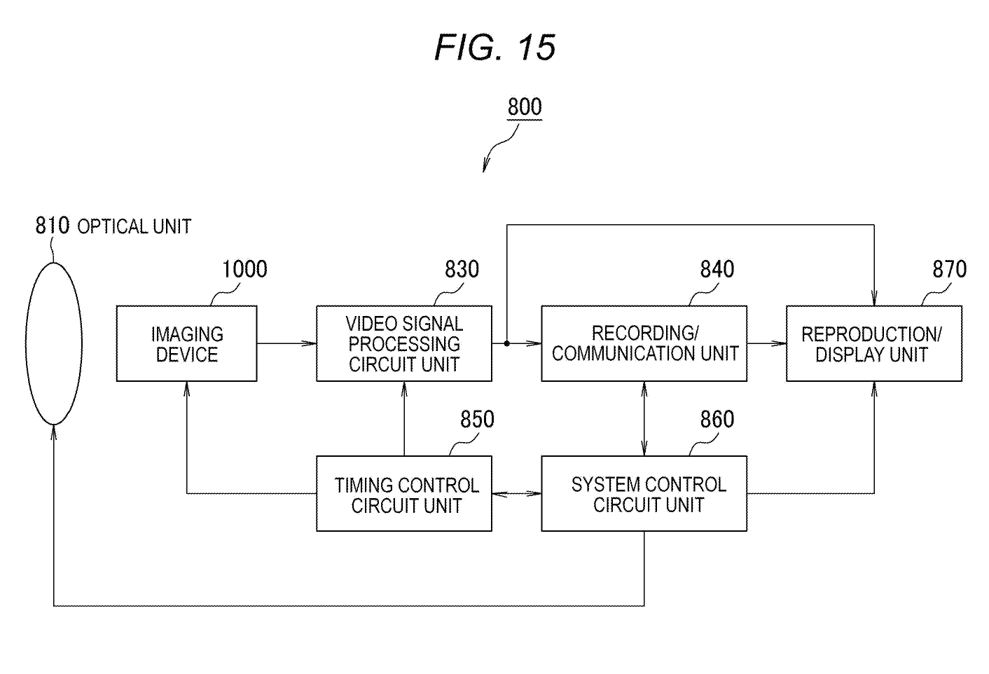

FIG. 15 is a diagram illustrating a configuration example of an imaging system according to a third embodiment. An imaging system 800 includes, for example, an optical unit 810, an imaging device 1000, a video signal processing circuit unit 830, a recording/communication unit 840, a timing control circuit unit 850, a system control circuit unit 860, and a reproduction/display unit 870. As the imaging device 1000, a solid-state imaging device described in the first and second embodiments can be used.

The optical unit 810 that is an optical system such as a lens focuses light from an object on a pixel array 100 of the imaging device 1000, and forms an image of the object. Note that the optical unit 810 can be deleted. The imaging device 1000 outputs a signal according to the light focused on the pixel array 100 at timing based on a signal from the timing control circuit unit 850. The signal output from the imaging device 1000 is input to the video signal processing circuit unit 830 that is a video signal processing unit. The video signal processing circuit unit 830 performs processing such as analog-digital (AD) conversion for the output signal of the imaging device 1000 according to a method determined by a program and the like. A signal generated by the processing in the video signal processing circuit unit 830 is output to the recording/communication unit 840 as image data. The recording/communication unit 840 outputs a signal for forming an image to the reproduction/display unit 870. A moving image and a still image are reproduced and displayed in the reproduction/display unit 870. Further, the recording/communication unit 840 inputs the signal from the video signal processing circuit unit 830, and performs communication with the system control circuit unit 860. In addition, the recording/communication unit 840 performs an operation to record the signal for forming an image on a recording medium (not illustrated).

The system control circuit unit 860 centrally controls the operation of the imaging system 800, and controls driving of the optical unit 810, the timing control circuit unit 850, the recording/communication unit 840, and the reproduction/display unit 870. Further, the system control circuit unit 860 includes a storage device (not illustrated) that is a recording medium, for example, and records programs and the like necessary for controlling the operation of the imaging system 800 in the storage device. Further, the system control circuit unit 860 supplies a signal that switches a drive mode according to an operation of the user, for example. Specific examples include change of a row to be read or a row to be reset, change of a field angle associated with electronic zooming, shift of a field angle associated with an electronic image stabilizing function, and the like. The timing control circuit unit 850 controls drive timing of the imaging device 1000 and the video signal processing circuit unit 830 based on the control of the system control circuit unit 860 as a control unit.

Note that all of the above-described embodiments are mere specific examples for implementing the embodiments, and the technical scope of the disclosure should not be construed by these embodiments in a limited manner. That is, the disclosure can be implemented in various forms without departing from the technical idea or the principal characteristics of the disclosure.

A fixed-pattern noise or color degrading in the sub-scanning direction caused due to the gap of timing at which the electric carrier accumulation of the first and second photoelectric conversion units is terminated can be decreased.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2014-008802, filed Jan. 21, 2014, which is hereby incorporated by reference herein in its entirety.

What is claimed is:

1. A solid-state imaging device configured to be relatively scanned in a first direction with respect to an original copy, the solid-state imaging device comprising:
a plurality of cells; and
a memory, wherein
each of the plurality of cells includes
a first photoelectric conversion unit configured to convert light into electric carriers and accumulate the electric carriers, and
a second photoelectric conversion unit arranged in the first direction with respect to the first photoelectric conversion unit, and configured to convert light into electric carriers and accumulate the electric carriers,
the memory is provided common to the first and second photoelectric conversion units, and holds the electric carriers accumulated by each of the first and second photoelectric conversion units, or signals based on the electric carries, and
an interval of the first and second photoelectric conversion units of one cell of the plurality of cells in the first direction is {n+(b/a)}×x, where a is a period from when the first and second photoelectric conversion units terminate electric carrier accumulation to when the first and second photoelectric conversion units perform the electric carrier accumulation again and next terminate the electric carrier accumulation, b is a gap of timing at which the electric carrier accumulation of the first and second photoelectric conversion units is terminated, n is an integer of 1 or more, and x is an interval of the first photoelectric conversion unit of the one cell of the plurality of cells, and the first photoelectric conversion unit of another cell adjacent to the one cell in a second direction perpendicular to the first direction.

2. The solid-state imaging device according to claim 1, wherein the interval of the first and second photoelectric conversion units in the first direction is {n+(b/a)+c}×x, and an absolute value of c is a value from 0.1 to 0.15, both inclusive.

3. A solid-state imaging device configured to be relatively scanned in a first direction with respect to an original copy, the solid-state imaging device comprising:
a plurality of cells; and
a memory, wherein
each of the plurality of cells includes
a first photoelectric conversion unit configured to convert light into electric carriers and accumulate the electric carriers, and
a second photoelectric conversion unit arranged in a second direction perpendicular to the first direction with respect to the first photoelectric conversion unit, and configured to convert light into electric carriers and accumulate the electric carriers,
the memory is provided common to the first and second photoelectric conversion units, and holds the electric carriers accumulated by each of the first and second photoelectric conversion units, or signals based on the electric carries, and
an interval of the first and second photoelectric conversion units of a same cell in the first direction is (b/a)×x, where a is a period from when the first and second photoelectric conversion units terminate electric carrier accumulation to when the first and second photoelectric conversion units perform the electric carrier accumulation again and next terminate the electric carrier accumulation, b is a gap of timing at which the electric carrier accumulation of the first and second photoelectric conversion units is terminated, and x is an interval of the first and second photoelectric conversion units of the same cell.

4. The solid-state imaging device according to claim 3, wherein the interval of the first and second photoelectric conversion units of the same cell in the first direction is {(b/a)+c}×x, and an absolute value of c is a value from 0.1 to 0.15, both inclusive.

5. The solid-state imaging device according to claim 1, wherein each of the plurality of cells further includes a floating diffusion configured to hold the electric carriers accumulated by each of the first and second photoelectric conversion units, as the memory.

6. The solid-state imaging device according to claim 5, wherein each of the plurality of cells further includes a reset transistor for resetting the floating diffusion to a reset voltage.

7. The solid-state imaging device according to claim 5, wherein each of the plurality of cells further includes a first transfer transistor configured to transfer the electric carriers accumulated by the first photoelectric conversion unit to the floating diffusion, and a second transfer transistor configured to transfer the electric carriers accumulated in the second photoelectric conversion unit to the floating diffusion, and
the gap of timing at which electric carrier accumulation of the first and second photoelectric conversion units is terminated is a gap between timing at which the first transfer transistor terminates the transfer of the electric carriers from the first photoelectric conversion unit to the floating diffusion, and timing at which the second transfer transistor terminates the transfer of the electric carriers from the second photoelectric conversion unit to the floating diffusion.

8. The solid-state imaging device according to claim 6, wherein each of the plurality of cells further includes a first transfer transistor configured to transfer the electric carriers accumulated by the first photoelectric conversion unit to the floating diffusion, and a second transfer transistor configured to transfer the electric carriers accumulated in the second photoelectric conversion unit to the floating diffusion, and
the gap of timing at which electric carrier accumulation of the first and second photoelectric conversion units is terminated is a gap between timing at which the first transfer transistor terminates the transfer of the electric carriers from the first photoelectric conversion unit to the floating diffusion, and timing at which the second transfer transistor terminates the transfer of the electric carriers from the second photoelectric conversion unit to the floating diffusion.

9. The solid-state imaging device according to claim 1, wherein the plurality of cells is provided in a same semiconductor substrate.

10. An imaging system comprising:
a solid-state imaging device according to claim 1; and
a signal processing unit configured to process an output signal of the solid-state imaging device.

11. A copier comprising:
a solid-state imaging device according to claim 1; and
a signal processing unit configured to process an output signal of the solid-state imaging device, wherein
the copier performs printing using a signal processed by the signal processing unit.
